(19) United States
(12) Patent Application Publication
(10) Pub. No.: US 2015/0245545 A1
(43) Pub. Date: Aug. 27, 2015

(54) BRAIDED ELECTROMAGNETIC SHIELDING FOR CABLES

(71) Applicant: NEXANS, Paris (FR)

(72) Inventors: Stephane Morice, Leforest (FR); Soizick Grendana, Fumay (FR); Jean-Jacques Sage, Suze-la-Rousse (FR)

(21) Appl. No.: 14/620,609

(22) Filed: Feb. 12, 2015

(30) Foreign Application Priority Data
Feb. 21, 2014 (FR) 14 51383

(51) Int. Cl. H05K 9/00

(52) U.S. Cl. CPC H05K 9/009; H05K 9/0098

(57) ABSTRACT

An electromagnetic cable shielding is provided having a braid including a plurality of wires in contact with one another. At least one wire has an oval cross section.

### RELATED APPLICATION

This application claims the benefit of priority from French Patent Application No. 14 51383, file on Feb. 21, 2014, the entirety of which is incorporated by reference.

### BACKGROUND

1. Field of the Invention

The invention relates to a braided electromagnetic shielding for cables, and in particular for electric cables.

2. Description of Related Art

Generally, an electromagnetic shielding is used to reduce the electromagnetic field in the vicinity of an object by inserting a barrier between the source of the field and the object to be protected. This barrier has to be produced with an electrically conductive material. In the context of an electric cable, this shielding often takes the form of a metal braid, placed tightly around said cable.

The existing metal braids, used as electromagnetic shieldings for these cables, in most cases involve wires of circular section, positioned alongside one another. A braid made up of wires of circular section thus makes it possible to ensure the suppleness and the flexibility of the cable, without damaging the shielding. Now, such braids present the drawback of using a large number of wires, resulting in a surplus of raw material and a long production time, and therefore high overhead costs.

### OBJECTS AND SUMMARY

A braid according to the invention, which is designed to ensure an electromagnetic shielding for a cable, makes it possible to overcome the drawbacks raised in the prior art.

The subject of the invention is an electromagnetic cable shielding, comprising a braid consisting of a plurality of wires in contact with one another.

The main feature of a shielding according to the invention is that at least one wire has an oval cross section. Thus, since each wire of oval cross section is brought into contact with the outer surface of the cable on the large side of said section, the braid therefore requires fewer wires to entirely cover said cable, compared to a configuration in which it would be made up only of wires of circular cross section. The result thereof is a reduced consumption of raw material to create these wires, therefore a shorter braid production time, and therefore a reduction in the production costs. With wires of oval cross section, the braid makes it possible to ensure a good suppleness and a good flexibility of the cable. The cable can, for example, be of electrical, optical or electronic type. The braid can thus consist, either partially or fully, of wires of oval cross section.

Preferentially, each wire of the braid has an oval cross section. According to this configuration, all the wires of the braid have an oval cross section.

Advantageously, the ratio between the length of the small side “a” of the oval cross section of each wire and the length of the large side “b” of said section lies between 45% and 90%. Such a ratio reflects the fact that each wire does not have to have an excessively flattened profile, which could compromise the flexibility and the suppleness of the cable. Furthermore, with wires that have such an oval cross section, the braid makes it possible to retain a good mechanical withstand strength.

Preferentially, said ratio lies between 60 and 70%. This is an optimized ratio that enables the braid to have a good mechanical withstand strength and to guarantee that the cable has a satisfactory flexibility and suppleness.

Preferentially, the wires have oval cross sections of different sizes.

Advantageously, the wires have oval cross sections of different forms.

Advantageously, the braid is made of metal.

Preferentially, the braid is made from a material to be chosen from copper, aluminum and steel.

Preferentially, the braid has at least two concentric layers of wires of oval cross section.

Advantageously, all the wires of the braid have an oval cross section, said wires being arranged in a spiral. In this way, the braid has a spiral geometry. Compared to a braid having twisted wires, a braid that has wires in spirals has a diameter which is reduced by 5% to 10%, and preferentially by 6% to 8%. In this way, through this reduction in diameter, an assembly formed by a cable and a braid is more flexible.

According to another embodiment of an electromagnetic shielding according to the invention, all the wires of the braid have an oval cross section, said wires being twisted together.

A second subject of the invention is an assembly comprising at least one cable and an electromagnetic shielding according to the invention.

The main feature of an assembly according to the invention is that the braid surrounds said at least one cable, being in contact therewith.

Advantageously, an assembly according to the invention comprises at least one electric cable.

An electromagnetic cable shielding according to the invention offers the advantage of being easy and quick to produce, in as much as the braid is made up of a reduced number of wires compared to an existing braid, consisting of wires of circular cross section. It further offers the advantage of having a reduced cost compared to that of an existing shielding, because of a reduction in the production time and a lesser quantity of raw material involved.

### BRIEF DESCRIPTION OF THE DRAWINGS

Hereinbelow, a detailed description is given of a preferred embodiment of an electromagnetic shielding according to the invention and of a cable/shielding assembly according to the invention, with reference to FIGS. 1 to 4B.

FIG. 1 is a schematic view in cross section of an assembly according to the invention, comprising a cable and an electromagnetic shielding according to the invention,

FIG. 2 is a schematic view in cross section of a wire of a braid of an electromagnetic shielding according to the invention,

FIGS. 3A, 3B, 3C are three schematic views in cross section of three consecutive wires of a braid of a shielding according to the invention, respectively at a stage without stress, at an intermediate stage of positioning around a cable and at a stage of final positioning around said cable,

FIGS. 4A and 4B are two schematic views in cross section of an example of three consecutive wires of a braid of a poorly dimensioned shielding, respectively at a stage of positioning without stress and at a stage of final positioning around said cable.

### DETAILED DESCRIPTION

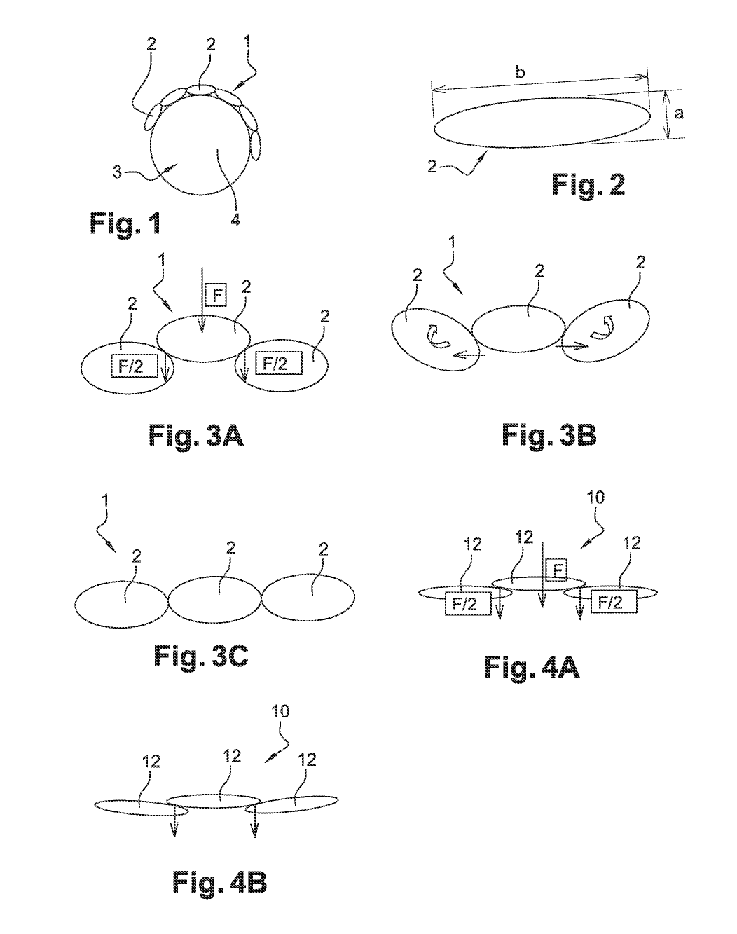

Referring to FIG. 1, an electromagnetic shielding according to the invention comprises a braid 1 consisting of a plurality of metal wires 2 of oval cross section. This braid 1 is placed around an electric cable 3 comprising at least one electrical conductor 4, which may or may not be surrounded by an insulating sheath. Each electrical conductor 4 has one or more metal wires, which can, for example, be of copper. Generally, it is important to stress that, to ensure an effective electromagnetic shielding, it is essential for the braid 1 to cover the outer surface of the cable 3 to the greatest possible extent. In other words, the rate of coverage of the braid 1 over the cable 3 should be maximum.

Referring to FIG. 2, each metal wire forming the braid 1 has an oval cross section characterized by a small side “a” and a large side “b”. It has been observed that, to obtain an efficient braid 1, both functionally and structurally, it is essential for the ratio of the length of the small side “a” to the length of the large side “b” to lie between 45% and 90%. In other words, it is essential that:

0.45≦a/b≦0.9

Preferentially, it has been observed that, for this braid 1 to have an optimum effectiveness, it is essential that:

0.6≦a/b≦0.7

Thus, with such a dimensioning of its wires 2, the braid 1 effectively fulfills its electromagnetic shielding function with respect to the cable 3, while guaranteeing a good flexibility and a good suppleness of said cable. Furthermore, with such wires, the braid has a good mechanical withstand strength.

The table below contains a comparison between different types of braid, surrounding a cable of constant diameter.

TABLE 1
comparison of the number of wires and of the material
saving obtained with different types of braids surrounding
a cable having a diameter of 5 mm.

| | Example | | | | |
|---|---|---|---|---|---|
| | | Oval | Oval | Oval | Oval |
| | Circle | a/b = 0.13/0.16 | 0.12/0.18 | 0.11/0.20 | 0.10/0.22 |
| Cable | 5 | 5 | 5 | 5 | 5 |
| diameter | | | | | |
| (mm) | | | | | |
| Diameter | 0.14 | 0.13-0.15 | 0.12-0.16 | 0.11-0.18 | 0.1-0.2 |
| of each | | | | | |
| wire of | | | | | |
| the braid | | | | | |
| (mm) | | | | | |
| Number of | 118 | 110 | 103 | 91 | 82 |
| wires | | | | | |
| Material | | 7% | 15% | 22% | 30% |
| saving | | | | | |
| as % | | | | | |

It emerges from this table that the more the wires of the braid are flattened (that is to say the more the ratio a/b decreases) the greater the material saving, because fewer wires are needed to make up the braid 1. By virtue of this advantage, it would therefore be tempting to choose wires 2 of the braid 1 that are as flattened as possible.

Now, referring to FIGS. 4A and 4B, if the wires 12 of the braid 10 are excessively flattened, it becomes difficult, even impossible, to obtain an optimum rate of coverage of the cable 3 by the braid 10. In effect, referring to FIG. 4A, by schematically applying a force F to such a first braid wire 10, this first wire 10 then transmits a force F/2 to the two adjacent wires 12 with which it is in contact.

Referring to FIG. 4B, these two wires 12 do not have the space to move apart to allow said first wire 12 to come into contact with the cable 3. Consequently, with excessively flattened wires 12, the rate of coverage of the braid 10 on the cable 3 is mediocre. Furthermore, this braid 10, when under mechanical tension, no longer guarantees that a good flexibility and a good suppleness of the cable 3 will be obtained.

It is therefore vitally important for each cable 2 of the braid 1 to have an oval cross section, observing certain limits in terms of dimensioning.

Thus, with wires 2 that have an oval cross section observing a ratio a/b lying between 45% and 90%, the rate of coverage of the braid 1 on the cable 3 can be optimized.

In effect, referring to FIG. 3, by schematically applying a force F to such a first braid wire 2, this wire then transmits a force F/2 to the two adjacent wires 2 with which it is in contact.

Referring to FIG. 3B, these two wires 2 react to this force F/2 by moving away from one another to allow the first wire 2 to pass.

Referring to FIG. 3C, the first wire 2 and the two adjacent wires 2 finish up lying perfectly aligned, to ensure an optimized coverage of the cable 3.

So as to increase the properties of the braid 1 as a function of the features of the cable 3 that it protects, the wires 2 that make up said braid 1 can have oval cross sections of different sizes and/or of different forms, and can be made from different metals.

Consequently, for a braid 1 according to the invention to be perfectly effective as electromagnetic shielding, while allowing a good flexibility and a good suppleness of the cable 3, the oval cross section of each wire 2 forming said braid 1 must observe certain proportions.

1. Electromagnetic cable shielding, comprising:
a braid having a plurality of wires in contact with one another, wherein at least one wire has an oval cross section.

2. Electromagnetic shielding according to claim 1, wherein each wire of the braid has an oval cross section.

3. Electromagnetic shielding according to claim 2, wherein the ratio between the length of the small side (a) of the oval cross section of each wire and the length of the large side (b) of said section lies between 45% and 90%.

4. Electromagnetic shielding according to claim 3, wherein said ratio lies between 60 and 70%.

5. Electromagnetic shielding according to claim 2, wherein the wires have oval cross sections of different sizes.

6. Electromagnetic shielding according to claim 2, wherein the wires have oval cross sections of different forms.

7. Electromagnetic shielding according to claim 2, wherein the braid is made from a material to be chosen from copper, aluminum and steel.

8. Electromagnetic shielding according to claim 2, wherein the braid has at least two concentric layers of wires of oval cross section.

9. Electromagnetic shielding according to claim 1, wherein all the wires of the braid have an oval cross section, and in that said wires are arranged in a spiral.

10. Electromagnetic shielding according to claim 1, wherein all the wires of the braid have an oval cross section, and in that said wires are twisted together.

11. Assembly comprising at least one cable and an electromagnetic shielding according to claim 1, wherein the braid surrounds said at least one cable, being in contact therewith.

12. Assembly according to claim 11, wherein said assembly further comprises at least one electric cable.
